(19) United States
(12) Patent Application Publication
(10) Pub. No.: US 2025/0237745 A1
(43) Pub. Date: Jul. 24, 2025

(54) Coherent LIDAR using Semiconductor Optical Amplifiers

(71) Applicant: SemiNex Corporation, Danvers, MA (US)

(72) Inventors: Sidi Aboujja, Middleton, MA (US); Daniel Yen Chu, Andover, MA (US); Ronald Moore, Boxford, MA (US)

(21) Appl. No.: 18/756,252

(22) Filed: Jun. 27, 2024

Related U.S. Application Data
(60) Provisional application No. 63/624,577, filed on Jan. 24, 2024.

(51) Int. Cl. G01S 7/481; G01S 7/499

(52) U.S. Cl. CPC G01S 7/4814; G01S 7/499

(57) ABSTRACT

A coherent LiDAR system including semiconductor optical amplifier that can boost the transmitter power into the Watt level as well as provide a means of pre-amplification of the return beam. This approach offers significant immunity to sunlight interference over a TOF LiDAR system and has the potential to operate over a wider range of atmospheric conditions because of the higher sensitivity of a coherent system's double balanced receiver configuration. The coherent receiver mixes a local oscillator signal with the received signal, the received signal must be an exact match to the transmitted signal's wavelength in order for the receiver to recognize the signal. This greatly reduces interference from sunlight and allows each LiDAR system to have a unique signature minimizing cross interference from another vehicle.

### RELATED APPLICATIONS

This application claims the benefit under 35 USC 119(e) of U.S. Provisional Application No. 63/624,577, filed on Jan. 24, 2024, which is incorporated herein by reference in its entirety.

### BACKGROUND OF THE INVENTION

LIDAR which is short for Light Detection and Ranging is a requirement for autonomous vehicle navigation. Significant success has been demonstrated with Time of Flight (TOF) LiDAR system but they are still not widely deployed. The LiDAR system needs to be able to image small objects such as people and larger objects such as automobiles, trucks and buses and it needs to be able to determine the range reliably under a wide range of sunlight and weather conditions. The other limitation on TOF is that a TOF flight system can only detect vehicle motion and direction by multiple sampling of the field of view and software interpolation of the vehicle's relative motion and direction which takes multiple scans to achieve. At highway speeds the ability to detect a fast-moving object to avoid a collision requires that the system be capable of near instantaneous detection of the object's speed and direction to provide the vehicle with sufficient time to react to the hazard. TOF LiDAR also has the issue of cross interference from other TOF LIDAR systems deployed in the environment as well as interference from the sun. While the system can be set up to operate at a specific wavelength of light to minimize cross interference, there is simply insufficient bandwidth to provide all vehicles with a unique TOF signature. The solar interference is minimized by providing a narrowband filter at the receiver, but this still allows some sunlight into the receiver which creates noise and reduces the signal to noise ratio which can compromise the detection and cause false signals. This complicates the problem of autonomous vehicle navigation in heavily congested areas and highways as well as when driving directly into the sun as certain times of the day and certain directions. These limitations of the TOF LiDAR systems are part of the reason along with cost of why they are not used widely.

### SUMMARY OF THE INVENTION

A coherent LiDAR system offers significant immunity to sunlight interference over a TOF LiDAR system and has the potential to operate over a wider range of atmospheric conditions because of the higher sensitivity of a coherent system's double balanced receiver configuration. The coherent receiver mixes a local oscillator signal with the received signal, the received signal must be an exact match to the transmitted signal's wavelength in order for the receiver to recognize the signal. This greatly reduces interference from sunlight and allows each LiDAR system to have a unique signature minimizing cross interference from another vehicle. Since the coherent laser must have a long coherence length, it is now possible to assign unique frequencies to each LiDAR system produced, much like a key code, to minimize the possibility of cross interference. However, coherent LIDAR systems based on semiconductor lasers are limited by the amount of power available at the transmitter. Most long coherence length single mode lasers are relatively low in power, typically less than a few hundred milliwatts. This invention is a semiconductor optical amplifier that can boost the transmitter power into the Watt level as well as provide a means of pre-amplification of the return beam.

In accordance with the present invention, LiDAR systems as set forth in the independent claims, respectively, are provided. Preferred embodiments of the inventions are described in the dependent claims.

In addition, in accordance with the present invention, the following LiDAR systems are further featured:
1. A coherent Light Detection and Range (LiDAR) system that uses a seed laser and a high-power semiconductor optical amplifier in the transmitter in combination with a high gain semiconductor optical amplifier in the receiver to improve the range capabilities of the system.
2. The LiDAR system of claim 1 that uses a tunable laser as the seed laser.
3. The LIDAR system of claim 1 that uses a narrow-band optical filter between the semiconductor optical amplifier in the receiver and the photo-detectors to block the broadband spontaneous emission from the amplifier.
4. The LiDAR system of claim 1 that uses a single step index semiconductor optical amplifier with a real index step created by a 3 μm, 4 μm or 5 μm rib to amplify the seed laser to 100 mW, 200 mW, 500 mW or greater and low AR coatings on the input and output facet. The AR coatings are 1% or lower reflectivity to reduce feedback reflections.
5. The LiDAR system of claim 1 that uses a single step index semiconductor optical amplifier with a real index step created by a 3 μm, 4 μm or 5 μm rib at a 4 degree or greater angle from normal to the output or input facet to amplify the master oscillator to 100 mW, 200 mW, 500 mW or greater where the rib can be straight or curved or have multiple curves where i is the number of curves and i>1 as long as the exit of the rib is at an angle to the output facet and low AR coatings on the input and output facet. The AR coatings are 1% or lower reflectivity to reduce feedback reflections.
6. The LiDAR system of claim 1 that uses a single step index semiconductor optical amplifier with a real index step created by a 3 μm, 4 μm or 5 μm rib at a 4 degree or greater angle from normal to the input and output facets to amplify the master oscillator to 100 mW, 200 mW, 500 mW or greater where the rib between the facets can have multiple curves where i is the number of curves and i>1 as long as the input and exit of the rib are at an angle to the input and output facets and low AR coatings on the input and output facet. The AR coatings are 1% or lower reflectivity to reduce feedback reflections.
7. The LiDAR system of claim 1 that uses a gain guided semiconductor optical amplifier with a gain guided index lateral confinement created by a 10 μm stripe, a 20 μm stripe, a 30 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower to reduce feedback reflections.
8. The LiDAR system of claim 1 that uses a gain guided semiconductor optical amplifier with a gain guided index lateral confinement at an angle of 4 degrees or greater from normal with respect to the output and input facet created by a 10 μm stripe, a 20 μm stripe, a 30 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower reflectivity to reduce feedback reflections.
9. The LiDAR system of claim 1 that uses a tapered gain guided semiconductor optical amplifier with a single mode injection port to amplify the master oscillator to 1 Watts, 2 Watts, or 3 Watts or greater with a stripe that tapers from 3 μm, 4 μm or 5 μm to 50 μm, 60 μm or larger and the single mode rib section can be straight or curved prior to the taper and low AR coatings on the input and output facet. The AR coatings are 1% or lower reflectivity to reduce feedback reflections.
10. The LiDAR system of claim 1 that uses a tapered gain guided semiconductor optical amplifier with a single mode injection port to amplify the master oscillator to 1 Watts, 2 Watts, or 3 Watts or greater with a contact stripe that tapers from 3 μm, 4 μm or 5 μm to 20 μm, 50 μm, 60 μm or larger and is tilted at an angle of 4 degrees or greater from normal with respect to the output facet and the single mode rib section can be straight or curved prior to the taper and low AR coatings on the input and output facet. The AR coatings are 1% or lower reflectivity to reduce feedback reflections.
11. The LIDAR system of claim 1 where the master oscillator and a power splitting waveguide is used to create a separate output port on the chip to provide a local oscillator signal to a coherent detection system. The power splitting waveguide may be at any angle of 1°, 2°, 3° or more depending on the power needed for the local oscillator. The port may exit the front facet, the back facet or the sides of the device. All exits will be AR coated with a low AR coating of 1% or less reflectivity.
12. The LIDAR system of claim 1 where the master oscillator is integrated on the same chip as the power splitter and a semiconductor optical amplifier with separate electrical connections to independently power the master oscillator and the power amplifier.
13. The LiDAR system of claim 1 that uses a frequency modulated laser to measure the range of the object when the frequency modulation is ramped up and down in a sawtooth pattern.
14. The LiDAR system of claim 1 that uses a frequency modulated laser to measure the velocity of the object when the frequency modulation is ramped up and down in a sawtooth pattern.
15. The LiDAR system of claim 1 that uses a frequency modulated laser to measure the range of the object when the frequency modulation is ramped up and down in a sinusoidal pattern.
16. The LiDAR system of claim 1 that uses a frequency modulated laser to measure the velocity of the object when the frequency modulation is ramped up and down in a sinusoidal pattern.
17. The LIDAR system of claim 1 that uses a doppler shift of the return beam to measure the velocity of the object.
18. The LiDAR system of claim 1 that uses the micro-doppler spectrum to characterize the vibration spectrum of the object.
19. The LiDAR system of claim 1 that uses a pseudo-random code to measure the range of the object.
20. The LiDAR system of claim 1 that uses a pseudo-random code to measure the velocity of the object.
21. The LiDAR system of claim 1 that uses a single step index semiconductor optical amplifier with a real index step created by a 3 μm, 4 μm or 5 μm rib to amplify the return signal with 10 dB, 20 dB, and 30 dB or more gain.
22. The LiDAR system of claim 1 that uses a single step index semiconductor optical amplifier with a real index step created by a 3 μm, 4 μm or 5 μm rib at a 4-degree angle to the input and output facet to amplify the return signal with 10 dB, 20 dB, and 30 dB or more gain and low AR coatings on the input and output facet. The AR coatings are 1% or lower reflectivity to reduce feedback reflections.
23. The LiDAR system of claim 1 that uses a single step index semiconductor optical amplifier with a real index step created by a 3 μm, 4 μm or 5 μm rib at a 4-degree angle to the output facet to amplify the return signal with 10 dB, 20 dB, and 30 dB or more small signal gain and low AR coatings on the input and output facet. The AR coatings are 1% or lower reflectivity to reduce feedback reflections.
24. The LiDAR system of claim 1 that uses a lens pair to couple the output of the single junction master oscillator to the multi-junction epi-structure where n is the number of junctions and n>1.
25. The LiDAR system of claim 1 that uses a pseudo-random code to determine the distance and velocity of the object.
26. The LiDAR system of claim 1 that uses phase modulation to determine the distance and velocity of the object.
27. The LiDAR system of claim 1 that operates at a wavelength in the band of 1225 nm-1700 nm.
28. The LiDAR system of claim 1 that uses a multi-junction epi-structure for the semiconductor optical amplifier where n is the number of junctions and n>1.
29. The LiDAR system of claim 1 that is integrated into a GaAs photonic integrated chip.
30. The LiDAR system of claim 1 that is integrated into a Silicon photonic integrated chip.
31. The LIDAR system of claim 1 that is integrated into an InP photonic integrated chip.
32. A scanning coherent Light Detection and Range (LiDAR) system that uses a seed laser and a high-power semiconductor optical amplifier in the transmitter to improve the range capabilities of the system.
33. The LiDAR system of claim 32 that uses a tunable laser as the seed laser.
34. The LiDAR system of claim 32 that uses a single step index semiconductor optical amplifier with a real index step created by a 3 μm, 4 μm or 5 μm rib to amplify the master oscillator to 100 mW, 200 mW, 500 mW or greater and low AR coatings on the input and output facet. The AR coatings are 1% or lower reflectivity to reduce feedback reflections.
35. The LiDAR system of claim 32 that uses a single step index semiconductor optical amplifier with a real index step created by a 3 μm, 4 μm or 5 μm rib at a 4 degree or greater angle from normal to the output facet to amplify the master oscillator to 100 mW, 200 mW, 500 mW or greater where the rib can be straight or curved or have multiple curves where i is the number of curves and i>1 as long as the exit of the rib is at an angle to the output facet and low AR coatings on the input and output facet. The AR coatings are 1% or lower reflectivity to reduce feedback reflections.
36. The LiDAR system of claim 32 that uses a single step index semiconductor optical amplifier with a real index step created by a 3 μm, 4 μm or 5 μm rib at a 4 degree or greater angle from normal to the input and output facets to amplify the master oscillator to 100 mW, 200 mW, 500 mW or greater where the rib can be straight or curved or have multiple curves where i is the number of curves and i>1 as long as the exit of the rib is at an angle to the output facet and low AR coatings on the input and output facet. The AR coatings are 1% or lower reflectivity to reduce feedback reflections.
37. The LiDAR system of claim 32 that uses a gain guided stripe semiconductor optical amplifier with a gain guided index lateral confinement created by a 10 μm stripe, a 20 μm stripe, a 30 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower reflectivity to reduce feedback reflections.
38. The LiDAR system of claim 32 that uses a gain guided strip semiconductor optical amplifier with a gain guided index lateral confinement at an angle of 4 degrees or greater from normal with respect to the output and input facet created by a 10 μm stripe, a 20 μm stripe, a 30 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower reflectivity to reduce feedback reflections.
39. The LiDAR system of claim 32 that uses a tapered gain guided semiconductor optical amplifier with a single mode injection port to amplify the master oscillator to 1 Watts, 2 Watts, or 3 Watts or greater with a stripe that tapers from 3 μm, 4 μm or 5 μm to 20 μm, 30 μm or larger and the single mode rib section can be straight or curved prior to the taper and low AR coatings on the input and output facet. The AR coatings are 1% or lower reflectivity to reduce feedback reflections.
40. The LiDAR system of claim 32 that uses a tapered gain guided semiconductor optical amplifier with a single mode injection port to amplify the master oscillator to 1 Watts, 2 Watts, or 3 Watts or greater with a stripe that tapers from 3 μm, 4 μm or 5 μm to 20 μm, 30 μm or larger and is tilted at an angle of 4 degrees or greater with respect to the output facet and the single mode rib section can be straight or curved prior to the taper and low AR coatings on the input and output facet. The AR coatings are 1% or lower reflectivity to reduce feedback reflections.
41. The LIDAR system of claim 32 where the master oscillator and a power splitting waveguide are used to create a separate output port on the chip to provide a local oscillator signal to a coherent detection system. The power splitting waveguide may be at any angle of 1°, 2°, 3° or more depending on the power needed for the local oscillator. The port may exit the front facet, the back facet or the sides of the device. All exits will be AR coated with a low AR coating of 1% or less reflectivity.
42. The LIDAR system of claim 32 where the master oscillator is integrated on the same chip as the power splitter and a semiconductor optical amplifier with separate electrical connections to independently power the master oscillator and the power amplifier.
43. The LiDAR system of claim 32 that uses a frequency modulated laser to measure the range of the object when the frequency modulation is ramped up and down in a sawtooth pattern.
44. The LiDAR system of claim 32 that uses a frequency modulated laser to measure the velocity of the object when the frequency modulation is ramped up and down in a sawtooth pattern.
45. The LiDAR system of claim 32 that uses a frequency modulated laser to measure the range of the object when the frequency modulation is ramped up and down in a sinusoidal pattern.
46. The LiDAR system of claim 32 that uses a frequency modulated laser to measure the velocity of the object when the frequency modulation is ramped up and down in a sinusoidal pattern.
47. The LIDAR system of claim 32 that uses a doppler shift of the return beam to measure the velocity of the object.
48. The LiDAR system of claim 32 that uses the micro-doppler spectrum to characterize the vibration spectrum of the object.
49. The LiDAR system of claim 32 that uses a pseudo-random code to measure the range of the object.
50. The LiDAR system of claim 32 that uses a pseudo-random code to measure the velocity of the object.
51. The LiDAR system of claim 32 that uses a polygon mirror with a different angle on each vertical facet to scan both the horizontal and vertical field of regard creating a 3-D range map.
52. The LiDAR system of claim 32 that uses a grating and large frequency modulation of the master oscillator to steer the beam in the field of regard and a second grating to create a 3-D range map.
53. The LiDAR system of claim 32 that uses mirrors mounted on 2 galvanometer motors to scan both the horizontal and vertical field of regard creating a 3-D range map.
54. The LiDAR system of claim 32 that uses vibrating mirrors to scan both the horizontal and vertical field of regard creating a 3-D range map.
55. The LiDAR system of claim 32 that uses two non-linear crystals such as Lithium Niobate to scan the field of regard creating a 3-D range map.
56. The LiDAR system of claim 32 that uses thin film non-linear crystals such as LiNbO₃, LiTaO₃, DKDP, KTP, BBO and NH₄H₂PO₄ADP and other crystals capable of being used as an electro-optic modulator, integrated on a silicon substrate to create a monolithic photonic integrated circuit LiDAR system.
57. The LiDAR system in claim 32 that has an array of semiconductor optical amplifiers seeded by a single tunable laser or multiple tunable lasers that are independently electrically addressable to allow scanning the field of view through an optical element.
58. The LIDAR system of claim 32 that uses a narrow-band optical filter between the semiconductor optical amplifier in the receiver and the photo-detectors to block the broadband spontaneous emission from the amplifier.
59. The LiDAR system in claim 32 that is an optical phased array of semiconductor optical amplifiers seeded by a single tunable laser with integral phase modulators to enable electronic beam steering of the far-field over the field of view.
60. The LIDAR system of claim 32 that uses a Risley prism pair to scan the transmitted laser beam and receive the transmitted laser beam producing a 3-dimensional representation of the field of view.
61. The LiDAR system of claim 32 that uses a pseudo-random code to determine the distance and velocity of the object.
62. The LiDAR system of claim 32 that uses phase modulation to determine the distance and velocity of the object.
63. The LiDAR system of claim 32 that operates at a wavelength in the band of 1225 nm-1700 nm.
64. The LiDAR system of claim 32 that uses a multi-junction epi-structure for the semiconductor optical amplifier where n is the number of junctions and n>1.
65. The LiDAR system of claim 32 that uses a lens pair to couple the output of the single junction master oscillator to the multi-junction epi-structure where n is the number of junctions and n>1.
66. The LiDAR system of claim 32 that uses an optical phased array chip based on metasurfaces to steer the beam electronically in the field of view.
67. The LiDAR system of claim 32 that uses a mechanical micro-electromechanical mirror system to steer the beam.
68. The LiDAR system of claim 32 that is integrated into a GaAs photonic integrated chip.
69. The LiDAR system of claim 32 that is integrated into a Silicon photonic integrated chip.
70. The LiDAR system of claim 32 that is integrated into an InP photonic integrated chip.
71. A scanning coherent Light Detection and Range (LiDAR) system that uses a seed laser and a high-power semiconductor optical amplifier in the transmitter and a high gain semiconductor optical amplifier in the receiver to improve the range capabilities of the system.
72. The LiDAR system of claim 71 that uses a tunable laser as the seed laser.
73. The LiDAR system of claim 71 that uses a single step index semiconductor optical amplifier with a real index step created by a 3 μm, 4 μm or 5 μm rib to amplify the master oscillator to 100 mW, 200 mW, 500 mW or greater.
74. The LiDAR system of claim 71 that uses a single step index semiconductor optical amplifier with a real index step created by a 3 μm, 4 μm or 5 μm rib at a 4 degree or greater angle from normal to the output or input facet to amplify the master oscillator to 100 mW, 200 mW, 500 mW or greater where the rib can be straight or curved or have multiple curves where i is the number of curves and i>1 as long as the exit of the rib is at an angle to the output facet and low AR coatings on the input and output facet. The AR coatings are 1% or lower reflectivity to reduce feedback reflections.
75. The LiDAR system of claim 71 that uses a single step index semiconductor optical amplifier with a real index step created by a 3 μm, 4 μm or 5 μm rib at a 4 degree or greater angle from normal to the input and output facets to amplify the master oscillator to 100 mW, 200 mW, 500 mW or greater where the rib can be straight or curved or have multiple curves where i is the number of curves and i>1 as long as the exit of the rib is at an angle to the output facet and low AR coatings on the input and output facet. The AR coatings are 1% or lower reflectivity to reduce feedback reflections.
76. The LiDAR system of claim 71 that uses a gain guided stripe semiconductor optical amplifier with a gain guided index lateral confinement created by a 10 μm stripe, a 20 μm stripe, a 50 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower reflectivity to reduce feedback reflections.
77. The LiDAR system of claim 71 that uses a gain guided strip semiconductor optical amplifier with a gain guided index lateral confinement at an angle of 4 degrees or greater from normal with respect to the output and input facet created by a 10 μm stripe, a 20 μm stripe, a 30 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower reflectivity to reduce feedback reflections.
78. The LiDAR system of claim 71 that uses a tapered gain guided semiconductor optical amplifier with a single mode injection port to amplify the master oscillator to 1 Watts, 2 Watts, or 3 Watts or greater with a stripe that tapers from 3 μm, 4 μm or 5 μm to 20 μm, 30 μm or larger and the single mode rib section can be straight or curved prior to the taper and low AR coatings on the input and output facet. The AR coatings are 1% or lower reflectivity to reduce feedback reflections.
79. The LiDAR system of claim 97 that uses a tapered gain guided semiconductor optical amplifier with a single mode injection port to amplify the master oscillator to 1 Watts, 2 Watts, or 3 Watts or greater with a stripe that tapers from 3 μm, 4 μm or 5 μm to 20 μm, 30 μm or larger and is tilted at an angle of 4 degrees or greater from normal with respect to the output facet and the single mode rib section can be straight or curved prior to the taper and low AR coatings on the input and output facet. The AR coatings are 1% or lower reflectivity to reduce feedback reflections.
80. The LIDAR system of claim 71 where the master oscillator and a power splitting waveguide are used to create a separate output port on the chip to provide a local oscillator signal to a coherent detection system. The power splitting waveguide may be at any angle of 1°, 2°, 3° or more depending on the power needed for the local oscillator. The port may exit the front facet, the back facet or the sides of the device. All exits will be AR coated with a low AR coating of 1% or less reflectivity.
81. The LIDAR system of claim 71 where the master oscillator is integrated on the same chip as the power splitter and a semiconductor optical amplifier with separate electrical connections to independently power the master oscillator and the power amplifier.
82. The LiDAR system of claim 71 that uses a frequency modulated laser to measure the range of the object when the frequency modulation is ramped up and down in a sawtooth pattern.
83. The LiDAR system of claim 71 that uses a frequency modulated laser to measure the velocity of the object when the frequency modulation is ramped up and down in a sawtooth pattern.
84. The LiDAR system of claim 71 that uses a frequency modulated laser to measure the range of the object when the frequency modulation is ramped up and down in a sinusoidal pattern.
85. The LiDAR system of claim 71 that uses a frequency modulated laser to measure the velocity of the object when the frequency modulation is ramped up and down in a sinusoidal pattern.
86. The LIDAR system of claim 71 that uses a doppler shift of the return beam to measure the velocity of the object.
87. The LiDAR system of claim 71 that uses the micro-doppler spectrum to characterize the vibration spectrum of the object.
88. The LiDAR system of claim 71 uses a pseudo-random code to measure the range of the object.
89. The LiDAR system of claim 97 that uses a pseudo-random code to measure the velocity of the object.
90. The LiDAR system of claim 71 uses a polygon mirror with a different angle on each vertical facet to scan both the horizontal and vertical field of regard creating a 3-D range map.
91. The LiDAR system of claim 71 that uses a grating and large frequency modulation of the master oscillator to steer the beam in the field of regard and a second grating to create a 3-D range map.
92. The LiDAR system of claim 71 that uses mirrors mounted on 2 galvanometer motors to scan both the horizontal and vertical field of regard creating a 3-D range map.
93. The LiDAR system of claim 71 that uses vibrating mirrors to scan both the horizontal and vertical field of regard creating a 3-D range map.
94. The LiDAR system of claim 71 that uses two non-linear crystals such as Lithium Niobate to scan the field of regard creating a 3-D range map.
95. The LiDAR system of claim 71 that uses thin film non-linear crystals such as LiNbO₃, LiTaO₃, DKDP, KTP, BBO and NH₄H₂PO₄ADP and other crystals capable of being used as an electro-optic modulator, integrated on a silicon substrate to create a monolithic photonic integrated circuit LiDAR system.
96. The LIDAR system of claim 71 that uses a Risley prism pair to scan the transmitted laser beam and receive the transmitted laser beam producing a 3-dimensional representation of the field of view.
97. The LiDAR system of claim 71 that uses a single step index semiconductor optical amplifier with a real index step created by a 3 μm, 4 μm or 5 μm rib to amplify the return signal with 10 dB, 20 dB, and 30 dB or more gain and low AR coatings on the input and output facet. The AR coatings are 1% or lower reflectivity to reduce feedback reflections.
98. The LiDAR system of claim 71 that uses a single step index semiconductor optical amplifier with a real index step created by a 3 μm, 4 μm or 5 μm rib at a 4-degree angle to the input and output facet to amplify the return signal with 10 dB, 20 dB, and 30 dB or more gain and low AR coatings on the input and output facet. The AR coatings are 1% or lower reflectivity to reduce feedback reflections.
99. The LiDAR system of claim 71 that uses a single step index semiconductor optical amplifier with a real index step created by a 3 μm, 4 μm or 5 μm rib at a 4-degree angle to the output facet to amplify the return signal with 10 dB, 20 dB, and 30 dB or more gain and low AR coatings on the input and output facet. The AR coatings are 1% or lower reflectivity to reduce feedback reflections.
100. The LIDAR system of claim 71 that uses a narrow-band optical filter between the semiconductor optical amplifier in the receiver and the photo-detectors to block the broadband spontaneous emission from the amplifier.
101. The LiDAR system of claim 71 that has an array of semiconductor optical amplifiers seeded by a single tunable laser or multiple tunable lasers that are independently addressable to allow scanning the field of view through an optical element.
102. The LiDAR system of claim 71 that is an optical phased array of semiconductor optical amplifiers seeded by a single tunable laser with integral phase modulators to enable electronic beam steering of the far-field over the field of view.
103. The LiDAR system of claim 71 that uses phase modulation to determine the distance and velocity of the object.
104. The LiDAR system of claim 97 that operates at a wavelength in the band of 1225 nm-17000 nm.
105. The LiDAR system of claim 71 that uses a multi-junction epi-structure for the semiconductor optical amplifier where n is the number of junctions and n>1.
106. The LiDAR system of claim 71 that uses a lens pair to couple the output of the single junction master oscillator to the multi-junction epi-structure where n is the number of junctions and n>1.
107. The LiDAR system of claim 71 that uses an optical phased array chip based on metasurfaces to steer the beam electronically in the field of view.
108. The LiDAR system of claim 71 that uses a mechanical micro-electromechanical mirror system to steer the beam in the field of view.
109. The LiDAR system of claim 71 that is integrated into a GaAs photonic integrated chip.
110. The LiDAR system of claim 71 that is integrated into a Silicon photonic integrated chip.
111. The LiDAR system of claim 71 that is integrated into an InP photonic integrated chip.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is an illustration of how the beat frequency can be used to determine range and velocity.

FIG. 2 is a schematic diagram showing the key components of a state-of-the-art FMCW LiDAR system.

FIG. 3 is another schematic diagram showing the key components of a state-of-the-art FMCW LiDAR system.

FIG. 4 is a schematic diagram showing a single junction high power gain guided straight contact semiconductor optical amplifier configurations.

FIG. 5 is a schematic diagram showing single-junction high power tapered gain guided semiconductor optical amplifier configurations.

FIG. 6 is a schematic diagram showing single junction semiconductor optical amplifier at 1550 nm providing up to 500 mW of gain as a power amplifier and 30 dB small signal gain as a pre-amplifier for a receiver.

FIG. 7 is a schematic diagram showing a FMCW system using integrated master oscillator/local oscillator power splitter.

FIG. 8 is a schematic diagram showing a FMCW LiDAR system with high power semiconductor optical amplifier and semiconductor optical amplifier for receiver.

FIG. 9 is a schematic diagram showing a FMCW scanned LiDAR system with high power semiconductor optical amplifier for transmitter.

FIG. 10 is a schematic diagram showing a FMCW scanned LiDAR system with high power semiconductor optical amplifier for transmitter and pre-amplifier receiver.

FIG. 11 is a schematic diagram showing an Semiconductor Optical Amplifier epi-structure.

FIG. 12 is a schematic diagram showing an Semiconductor Optical Amplifier, mode field and transverse confinement.

FIG. 13 is a schematic diagram showing an Semiconductor Optical Amplifier band structure.

FIG. 14 is a schematic diagram showing a FMCW LIDAR using multiple individually addressable multi-junction semiconductor laser for scanning.

FIG. 15 is a schematic diagram showing a multiple curve waveguide formed by real index guiding rib where the number of curves can be 1 or greater even forming a “U”.

FIG. 16 is a schematic diagram showing a curved rib waveguide launching into a tapered gain guided section.

FIG. 17 is a schematic diagram showing a Triple Junction Semiconductor Optical Amplifier seed laser injection methods.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Also, all conjunctions used are to be understood in the most inclusive sense possible. Thus, the word “or” should be understood as having the definition of a logical “or” rather than that of a logical “exclusive or” unless the context clearly necessitates otherwise. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It will be understood that although terms such as “first” and “second” are used herein to describe various elements, these elements should not be limited by these terms. These terms are only used to distinguish one element from another element. Thus, an element discussed below could be termed a second element, and similarly, a second element may be termed a first element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

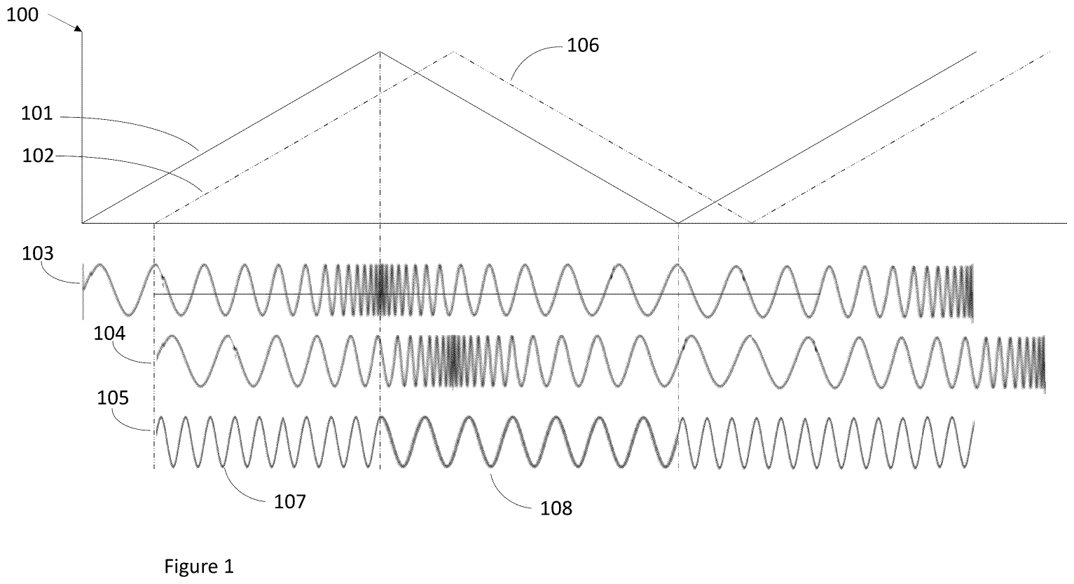

Frequency Modulated Continuous Wave (FMCW) (100) is a type of coherent laser radar where the transmitted laser signal is frequency modulated (103) in a particular modulation pattern such as saw-tooth (101,106), triangular, or rectangular. The return signal (104) is then mixed with the laser that is being frequency modulated and the beat frequency (105) between the two signals or frequency difference is a precise measure of the range of the target as shown in FIG. 1.¹ If the laser's frequency is being modulated linearly over a range of Δf for a given period of time tₛ. And the return signal is delayed by Δt, then the mixing of the return signal with the current frequency of the local oscillator will produce a beat frequency (107) which is the difference between the original frequency and the frequency of the laser at time Δt. The range of the object is then given by the following equation:

$$Range = \frac{c * {f}_{b} * {t}_{s}}{2 * Δ f} \qquad 1$$

Where c is the speed of light
   f_{b} is the beat frequency between the LO and the delayed beam from the object.
   tₛ is the frequency sweep time which must be longer than the range being measured.
   Δf is the frequency chirp of the laser.

In order to determine the object velocity, it is necessary to take into account the modulation format. In FIG. 1, when a sawtooth frequency sweep is being used, then there are two returns from the target, the first is the beat frequency for the increasing frequency sweep (107), f_{b}⁺ and the beat frequency for the decreasing frequency sweep (108), f_{b}⁻ which provides the instantaneous velocity of the object:²

$$Velocity = \frac{c * ( {f}_{b}^{-} - {f}_{b}^{+} )}{4} \qquad 2$$

A major difference between the Time of Flight LIDAR and the FMCW LiDAR is the significant amount of post processing that is needed in the frequency domain. However, the improved sensitivity of the FMCW system makes it a very attractive alternative, but one major limitation is the low power levels of the single frequency tunable diode lasers that are available. These diode lasers have output power levels less than 100 mW but are easily tunable using the drive current to the laser diode. However, it was noted in reference 1 that the frequency chirp induced by a current change is not necessarily linear and the current drive waveform has to compensate for the non-linear change.

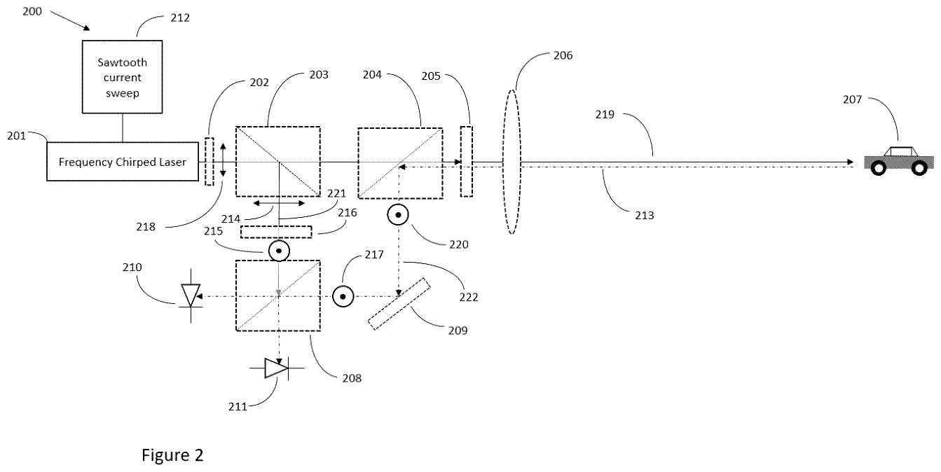

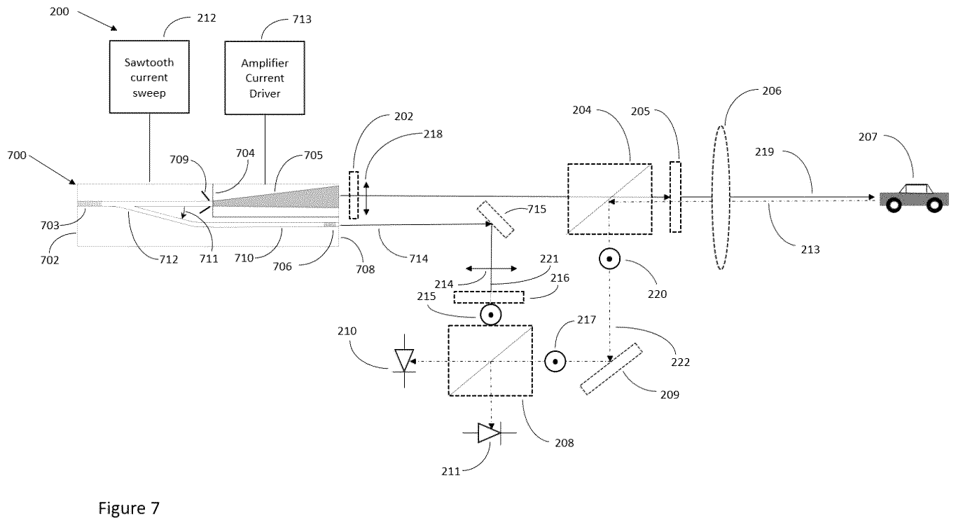

FIG. 2 shows a non-scanning state of the art FMCW system. The system can be implemented with free-space optics as shown in this figure, with fiber optical components or with integrated components as shown in FIG. 7. The laser frequency is controlled by an external current modulator (212) driving the laser (201) that provides the correct waveform to create a linear sweep of the laser's frequency (103). A typical sweep frequency span could be 3 GHz with a 1 kHz sawtooth sweep frequency. The system can use laser diode epi-material operating in the range of 1300 nm to 1700 nm. The output of the laser is collimated by the micro-optic or an optic (202) with polarization (218) and is split into two signals with a 90:10 beam splitter (203) with 90% or more of the power transmitted and 10% or less reflected with polarization (214) to be used as the local oscillator signal (221). The local oscillator signal (221) passes through a ½ waveplate to rotate its polarization to s-polarized (215) relative to the 50:50 beam splitter (208) and the return beam polarization (217). The high-power p-polarized output passes through the polarization beam splitter (204) and is converted to right circularly polarized light by a ¼ waveplate (205). The polarization beam splitter (204) transmits the p-polarized light (218) but will reflect the return s-polarized light (220). The beam is then transmitted to the field of view by the transmit/receive optic (206). The right circularly polarized beam (219) is converted to left circular polarization upon reflection from the remote object (207). The left circularly polarized scattered light (213) is sampled by the receive lens (206) (or telescope) and converted to s-polarized light (220), referenced to PBS cube (204), by the waveplate (205). The s-polarized light (222, 220) is reflected perpendicular to the path of propagation by the polarization beam splitter (204) to a mirror (209) and then to a 50:50 beam splitter (208). The received light (222) is mixed in the 50:50 beam splitter (208) with the local oscillator beam (221) to produce the beat frequency (105) between the current frequency (103) of the local oscillator and the delayed frequency (104) of the local oscillator. The double balanced receiver made up of photodiode 1 (210) and photodiode 2 (211) converts the optical signal into an electrical signal, in this case a current. The output of the double balance receiver is amplified by transconductance amplifiers, and the beat frequency (105) is analyzed by the FMCW receiver electronics to determine the distance and the speed of the object. A typical tunable laser diode such as a Thorlabs SFL1550 provides 40 mW of laser power, can be tuned over 3 GHz at a 1 kHz rate. Using a 25 mm diameter transmit beam, the performance of a system based on this laser diode is shown in Table 1.

TABLE 1
FMCW Range For 40 mW Laser and 25 mm transmit aperture

| | Clear | | | Haze | | | Moderate Fog 0.2 km visibility | | |
|---|---|---|---|---|---|---|---|---|---|
| | 10 cm target | | | 10 cm target | | | 10 cm target | | |
| Reflectivity | 10% | 50% | 80% | 10% | 50% | 80% | 10% | 50% | 80% |
| Range (m) | 230 | 490 | 620 | 200 | 370 | 440 | 70 | 90 | 100 |

Despite the significantly lower power than a Time-of-Flight laser diode, the performance is very similar even with the very low power levels as shown in Table 2.

TABLE 2
Detectable Range for TOF Compared to FMCW

| | | Clear | | | Haze | | | Moderate Fog 0.2 km visibility | | |
|---|---|---|---|---|---|---|---|---|---|---|
| | | 10 cm target | | | 10 cm target | | | 10 cm target | | |
| Target Reflectivity | Laser Power (W) | 10% | 50% | 80% | 10% | 50% | 80% | 10% | 50% | 80% |
| TOF Range (m) | 25 | 300 | 450 | 500 | 270 | 380 | 420 | 80 | 110 | 120 |
| FMCW Range (m) | 0.03 | 230 | 490 | 620 | 200 | 370 | 440 | 70 | 90 | 100 |

The FMCW laser power transmitted is less than the 40 mW output capability of the laser because 10 mW of laser power is diverted to the local oscillator at the receiver.

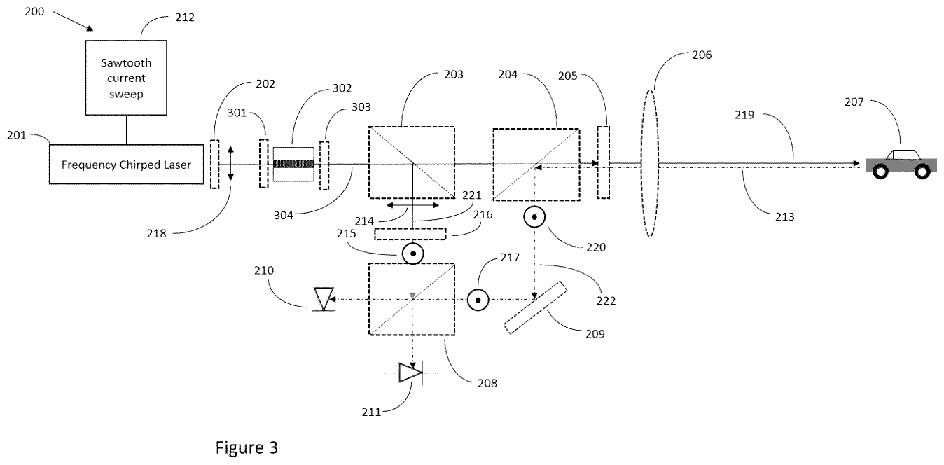

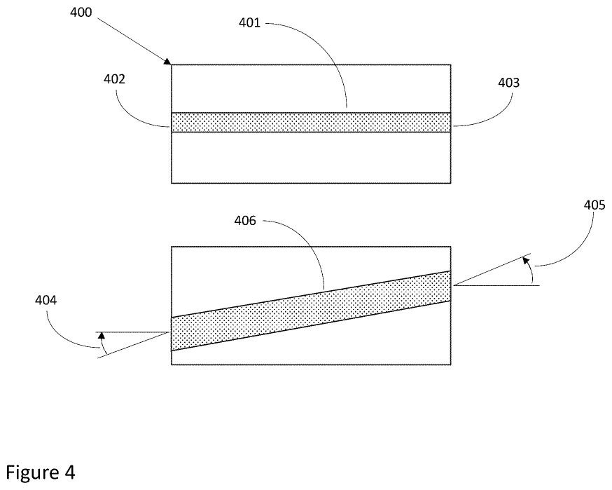

FIG. 3 is the first embodiment of the invention. The system can be implemented with free-space optics as shown in this figure or with fiber optical components. The laser frequency is controlled by an external current modulator (212, 101) that provides the correct waveform to create a linear sweep of the laser's frequency (103). A typical sweep frequency span could be 3 GHz with a 1 kHz sawtooth sweep frequency. The system can use laser diode epi-material operating in the range of 1300 nm to 1700 nm. The output of the laser is collimated by the micro-optic or an optic (202) and then coupled with an optic (301) into the semiconductor optical amplifier (302) which can be one of the designs shown in FIGS. 4 (400) and 5 (500). The angled design (406) is at an angle of 4 degrees from normal to the output facet (405) and input facet (404) with both coated with a low reflection coating.

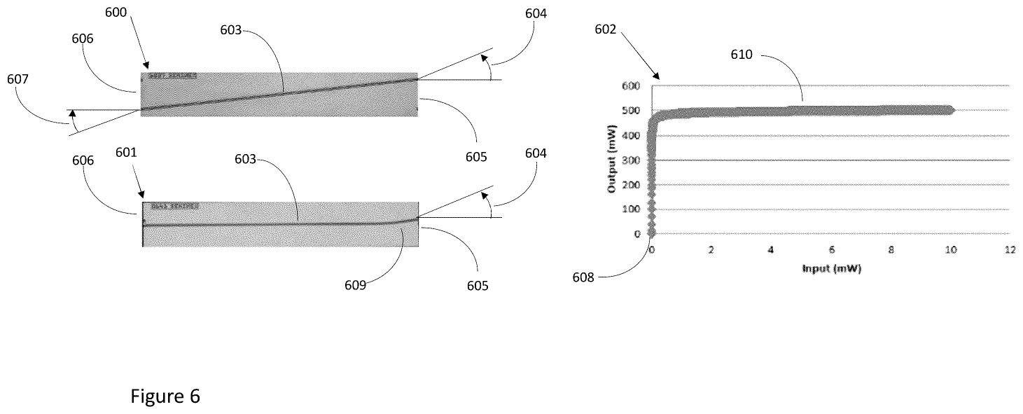

A 4 μm rib waveguide (603) can produce the amplifier performance (602) as shown in FIG. 6 and is capable of outputting 500 mWatts (610) of laser power and higher with less than 10 mWatts injected power (608). The angled design (600) is at an angle of 4 degrees from normal to the output facet (604) and input facet (607) with both facets coated with a low reflection coating (605,606). Another method to achieve this high performance is with a tilted output facet using a curved waveguide (607). Semiconductor optical amplifier (601) starts with a straight 4 μm rib from an AR coated facet (606) and curves near the end of the rib (609) or any position along the length of the rib, to enable the output facet to be tilted (604) with respect to the output facet to reduce back reflected power.

Using a wider stripe in FIG. 4, a 20 μm stripe when injected by a single mode source will maintain single mode operation and will be capable of 1 Watt of output power, a 40 μm stripe will be capable of 5 Watts of output power so the stripe width could be 10 μm, 20 μm, 40 μm or more.

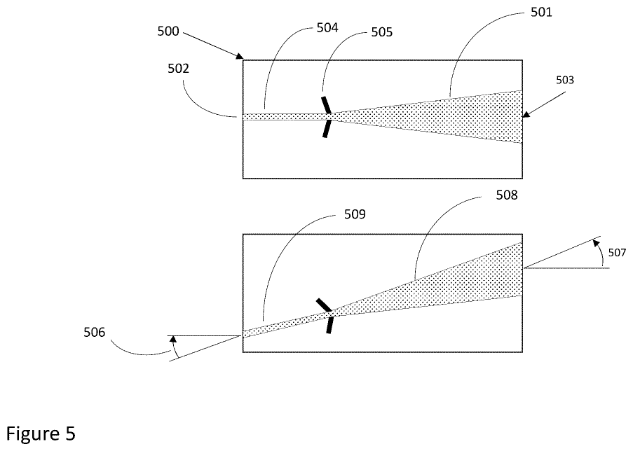

To achieve greater power levels, the design of FIG. 5 can produce power levels up to 10 Watts when the taper expands to 100 μm. The output of the semiconductor optical amplifier in FIG. 3 is split (203) with 10 mW of laser power (221,214) sampled to use as the local oscillator. The beam splitter can be a 90:10 for lower power lasers, 99:1 for higher power lasers or 99.9:0.1 for even high-power lasers. The beam may be split prior to the semiconductor optical amplifier (302) or after as shown in this figure. The local oscillator beam (214,221) passes through a ½ waveplate (216) to rotate the polarization to the s-polarization state (215) relative to the 50:50 Beam Splitter (208) and the Return Beam's polarization state (217). The p-polarized output passes through the polarization beam splitter (204) and is converted to right circularly polarized light by a ¾ waveplate (205). The beam (219) is then transmitted to the field of view by the transmit/receive optic (206). The right circularly polarized beam (219) is converted to left circular polarization upon reflection from the remote object (207). The left circularly polarized scattered light is sampled by the receive lens (206) (or telescope) and converted to s-polarized light, referenced to PBS cube (204), by the waveplate (205). The s-polarized light is reflected perpendicular to the path of propagation by the polarization beam splitter (204) to a mirror (209) and then to a 50:50 beam splitter (208). The received light (222) is mixed in the 50:50 beam splitter (208) with the local oscillator beam (221,215) to produce the beat frequency (105) between the current frequency (103) of the local oscillator and the delayed frequency (104) of the local oscillator. The double balanced receiver made up of photodiode 1 (210) and photodiode 2 (211) converts the optical signal into an electrical signal, in this case a current. The output of the double balance receiver is amplified by transconductance amplifiers, and the beat frequency is analyzed by the FMCW receiver electronics to determine the distance and the speed of the object. Table 3 shows the improvements in the range capabilities of the FMCW system for the three different power levels using a 25 mm diameter transmit/receive lens or telescope.

TABLE 3
A comparison of FMCW performance for different transmitter power levels

| | | CLEAR | | | HAZE | | | Moderate Fog 0.2 km visibility | | |
|---|---|---|---|---|---|---|---|---|---|---|
| | | 10 cm target | | | 10 cm target | | | 10 cm target | | |
| Reflectivity | Laser Power (W) | 10% | 50% | 80% | 10% | 50% | 80% | 10% | 50% | 80% |
| RANGE (m) | 0.03 | 230 | 490 | 620 | 200 | 370 | 440 | 70 | 90 | 100 |
| RANGE (m) | 0.5 | 870 | 1,520 | 1,700 | 560 | 910 | 1,030 | 110 | 140 | 150 |
| RANGE (m) | 1 | 1,190 | 1,790 | 1,990 | 700 | 1,090 | 1,220 | 130 | 160 | 170 |
| RANGE (m) | 10 | 2,090 | 3,000 | 3,330 | 1,280 | 1,630 | 1,740 | 170 | 200 | 210 |

The objective of the automobile industry is to achieve a 200 m detectable range for highway speeds even in moderate fog conditions. This table shows that these performance requirements are possible with 10 Watts of CW power at 1550 nm which is considered eyesafe. This type of LiDAR system can be set to a given power level as a function of the vehicle speed; at lower speeds the power can be decreased to the range needed for safely stopping a vehicle. Also, this system will only be in use when the vehicle is in motion.

A second embodiment of the LIDAR invention is shown in FIG. 7 with the frequency chirped laser (703,712,710,706), the local oscillator power sampler (712) and the semiconductor optical amplifier (705) all integrated onto a single chip (700). The semiconductor optical amplifier (705) can be one of the four designs illustrated in FIGS. 4 and 5. The back of the laser on the integrated chip (700) can be the back facet (702) which may be HR coated or a Bragg grating reflector (703). The output of the local oscillator may be a Bragg grating (706) if the back facet is HR coated and if a Bragg grating (703) is not used at the back of the device to establish the operating frequency of the laser. This section makes up the tunable laser by the metallization break (704) which enables the local oscillator section (702,703,712,710,706,708) to operate with the sawtooth current (212, 101) while the drive current (713) to the semiconductor optical amplifier can be held constant or switched on and off as needed. The preferred embodiment for the front facet (708) is a low AR coating<0.5% to minimize back reflections from the power amplifier section back into the master oscillator. One skilled in the art will also recognize that a weak Bragg grating (710) along the entire length of the local oscillator power arm will also provide single frequency, tunable operation of the local oscillator/master oscillator. The master oscillator/local oscillator now consists of the back facet (702), or the back Bragg grating (703), the front facet (708) or the front Bragg grating (708) whereby the operating wavelength of the master oscillator is determined by these elements, the power amplifier which can be at an angle to the output fact does not create any feedback that could interfere with the operation of the master oscillator section. One skilled in the art will recognize that the semiconductor optical amplifier (705) and the master oscillator/local oscillator branching leg (712) can be interchanged without impacting the operation of the device. The output of the integrated chip (700) now consists of the semiconductor optical amplifier power output (218,219) and the local oscillator signal (714). The power amplifier section of the chip (705) operates with nominal output from the master oscillator/local oscillator section, the amount of power delivered to the power amplifier section is determined by the splitting angle (711) of the branching waveguide (712) and the width of the waveguide section (710). Low angles of 1° results in low power being delivered to the power amplifier section while larger angles 5° or more result in higher power levels delivered to the power semiconductor optical amplifier section (705). Assuming the master oscillator/local oscillator (702,703,712,710,706,708) has a circulating power level of 100 mW or more, the splitting angle (711) can be large to sample 1-10 mW of laser power and send it to the power amplifier section (705). There are two deep trenches included in the design (709) which act as apertures into the tapered amplifier section. As shown in FIGS. 5 and 6, the power semiconductor optical amplifiers have exhibited a gain of 30 dB so an injected signal of 1 mW will produce a 500 mW output for a simple rib waveguide section. The output of the power semiconductor optical amplifier is collimated by the micro-optic (202), it is then transmitted through a polarization beam splitting cube (204), a ¼ waveplate (205) and a transmitting optic (206) to the target (207). The transmitted beam (219) is right circular polarized light leaving the transmitter. The reflection of the transmitted beam converts the right circularly polarized light to left circularly polarized light (213). The left circularly polarized light is received and converted by the ¼ waveplate (205) to s-polarized light which is then reflected in the polarization beam splitting cube (204) to the double balanced receiver (211,210) where the return beam is mixed with the local oscillator beam (714). It is apparent to one skilled in the art that the lidar system does not have to use a shared transmit/receive aperture, and the ¼ waveplate can be eliminated from the design, however the system will have separate transmit and receive optics.

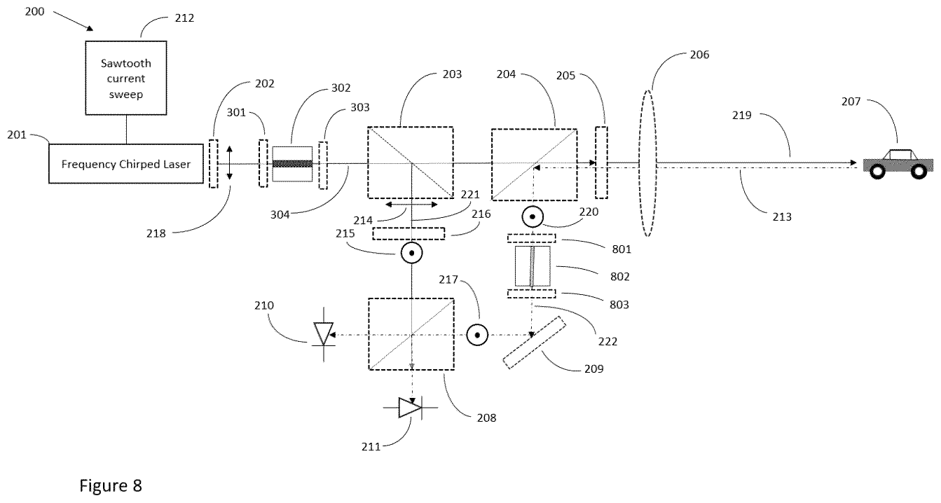

FIG. 8 is a third embodiment of the LiDAR invention. The system can be implemented with free-space optics as shown in this figure or with fiber optical components. The laser frequency is controlled by an external current modulator (212) that provides the correct waveform to create a linear sweep of the laser's frequency (101). A typical sweep frequency could be 3 GHz at a rate of 1 kHz. The system can use laser diode epi-material operating in the range of 1300 nm to 1700 nm. The output of the laser is collimated by the micro-optic or an optic (202) and then coupled into the semiconductor optical amplifier (301) which can be one of the designs shown in FIGS. 4 (400) and 5 (500). The output of the semiconductor amplifier (304) is split (203) with only 10 mW of laser power sampled to use as the local oscillator. The beam splitter can be a 90:10 for lower power lasers, 99:1 for higher power lasers or 99.9:0.1 for even high-power lasers. The local oscillator portion of the beam (221) passes through a ½ waveplate (216) to convert the beam to the s-polarized state (215) referenced to the 50:50 beam splitter (208) and the return beam (222,217). The p-polarized high power output passes through the polarization beam splitter (204) and is converted to right circularly polarized light by a ¼ waveplate (205). The beam is then transmitted to the field of view by the transmit/receive optic (206). The right circularly polarized beam (219) is converted to left circular polarization (213) upon reflection from the remote object (207). The left circularly polarized scattered light is sampled by the receive lens (206) (or telescope) and converted to s-polarized light, referenced to PBS cube (204), by the waveplate (205). The s-polarized light is reflected perpendicular to the path of propagation by the polarization beam splitter (804) to the micro-optic (801) which couples the return beam into the semiconductor optical amplifier (802). The return beam is amplified by 30 dB then outcoupled through the micro-optic (803). The amplified beam (222) is reflected by the mirror (209) and propagates through a 50:50 beam splitter (208). The amplified received light (222) is mixed in the 50:50 beam splitter (208) with the local oscillator beam (221,215) which results in the intensity of the beam being modulated (105) by the frequency difference (f_{b}) between the current frequency (103) of the local oscillator and the delayed frequency (105) of the local oscillator. The double balanced receiver made up of photodiode 1 (210) and photodiode 2 (211) converts the modulated optical signal into an electrical signal, in this case a current. The output of the double balance receiver is amplified by transconductance amplifiers, and the beat frequency is analyzed by the FMCW receiver electronics to determine the distance and the speed of the object. Table 4 shows the improvements in the range capabilities of the FMCW system for the three different power levels using a 25 mm diameter transmit/receive lens or telescope and a pre-amplifier at the receiver.

TABLE 4
FMCW Improved Range Performance with A Semiconductor Optical Amplifier Pre-Amplifier at Receiver

| | | CLEAR | | | HAZE | | | Moderate Fog 0.2 km visibility | | |
|---|---|---|---|---|---|---|---|---|---|---|
| | | 10 cm target | | | 10 cm target | | | 10 cm target | | |
| Reflectivity | Laser Power (W) | 10% | 50% | 80% | 10% | 50% | 80% | 10% | 50% | 80% |
| RANGE (m) | 0.03 | 2,680 | 3,810 | 4,200 | 1,520 | 1,900 | 2,020 | 190 | 220 | 100 |
| RANGE (m) | 0.5 | 4,890 | 6,720 | 7,340 | 2,220 | 2,680 | 2,820 | 250 | 280 | 290 |
| RANGE (m) | 1 | 5,620 | 7,650 | 8,340 | 2,410 | 2,890 | 3,040 | 260 | 300 | 310 |
| RANGE (m) | 10 | 8,680 | 11,440 | 12,340 | 3,110 | 3,640 | 3,800 | 310 | 350 | 360 |

A significant improvement in range capability of the FMCW LiDAR is achieved using both the higher power semiconductor optical amplifiers for the transmitter and the semiconductor optical amplifier for the receiver compared to the performance using state of the art lasers and receivers. One skilled in the art will recognize that the integrated master oscillator/local oscillator-power amplifier chip (700) described in FIG. 7 can replace the discrete components described in this embodiment.

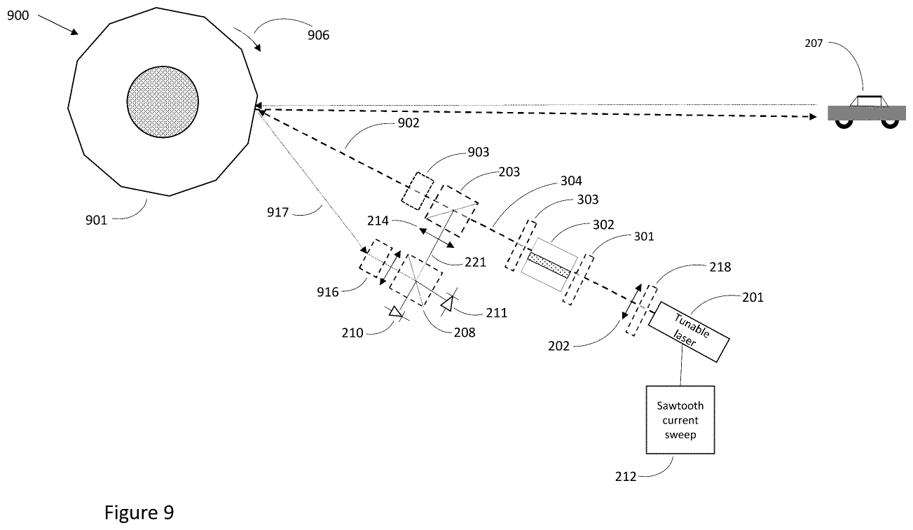

A fourth embodiment of the invention is shown in FIG. 9. The system can be implemented with free-space optics as shown in this figure or with fiber optical components. The frequency of the laser (201) is controlled by an external current modulator (211) that provides the correct waveform (101) to create a linear sweep of the laser's frequency (103). A typical sweep frequency could span 3 GHz with a 1 kHz sawtooth sweep frequency (101). The system can use laser diode epi-material operating in the range of 1300 nm to 1700 nm. The output of the laser is collimated by the micro-optic or an optic (202) and then coupled into the semiconductor optical amplifier (302) which can be one of the designs shown in FIGS. 4 (400) and 5 (500). The angled design (406) is at an angle of 4 degrees or more from normal to the output facet (405) and input facet (404) is coated with a low reflection coating. A 4 μm rib waveguide can produce the performance as shown in FIG. 6 and is capable of outputting 500 m Watts of laser power with less than 10 m Watts injected. The output of the semiconductor optical amplifier is split (203) with only 10 mW of laser power sampled to use as the local oscillator. The beam splitter can be a 90:10 for lower power lasers, 99:1 for higher power lasers or 99.9:0.1 for even high-power lasers. The beam splitter can also be between the tunable laser (201) and the semiconductor optical amplifier (302). The local oscillator beam (221,214) passes through a 50:50 beam splitter (208) to be mixed with the return beam (917). The high-power beam passes through the transmitter optics (903) to create a beam 5 mm in diameter. This beam reflects off the polygon scanning mirror (901) which has a different angle for each facet in the vertical direction, the motion (906) of the polygon mirror provides the horizontal scan and each facet provides a different horizontal scan in the vertical direction. The beam is assumed to scatter off the Lambertian target and a portion of the return beam reflects off the polygon mirror (901) which has moved slightly in the 12 nseconds required to complete a round trip at a 200 meter range. The received beam (917) is collected by a 25 mm diameter receiver optic (916). The received beam (917) is mixed with the local oscillator (221,214) in the 50:50 beam splitter. The mixing of the two beams results in an intensity modulation that is 90 degrees out of phase between the two detectors (211,210) creating a double balanced receiver. Each of the photodiode currents are amplified by a transimpedance amplifier before being analyzed by the receiver electronics to determine range and velocity of the object. One skilled in the art will recognize that the integrated master oscillator/local oscillator-power amplifier chip (700) described in FIG. 7 can replace the discrete components described in this embodiment.

TABLE 5
FMCW Performance for Scanned System with High Power Semiconductor Optical Amplifiers

| | | CLEAR | | | HAZE | | | Moderate Fog 0.2 km visibility | | |
|---|---|---|---|---|---|---|---|---|---|---|
| | | 10 cm target | | | 10 cm target | | | 10 cm target | | |
| Reflectivity | Laser Power (W) | 10% | 50% | 80% | 10% | 50% | 80% | 10% | 50% | 80% |
| RANGE (m) | 0.03 | 50 | 110 | 130 | 50 | 100 | 120 | 30 | 50 | 50 |
| RANGE (m) | 0.5 | 190 | 330 | 360 | 170 | 290 | 320 | 60 | 90 | 100 |
| RANGE (m) | 1 | 260 | 390 | 430 | 220 | 340 | 370 | 70 | 100 | 110 |
| RANGE (m) | 10 | 460 | 670 | 750 | 390 | 540 | 590 | 110 | 140 | 150 |

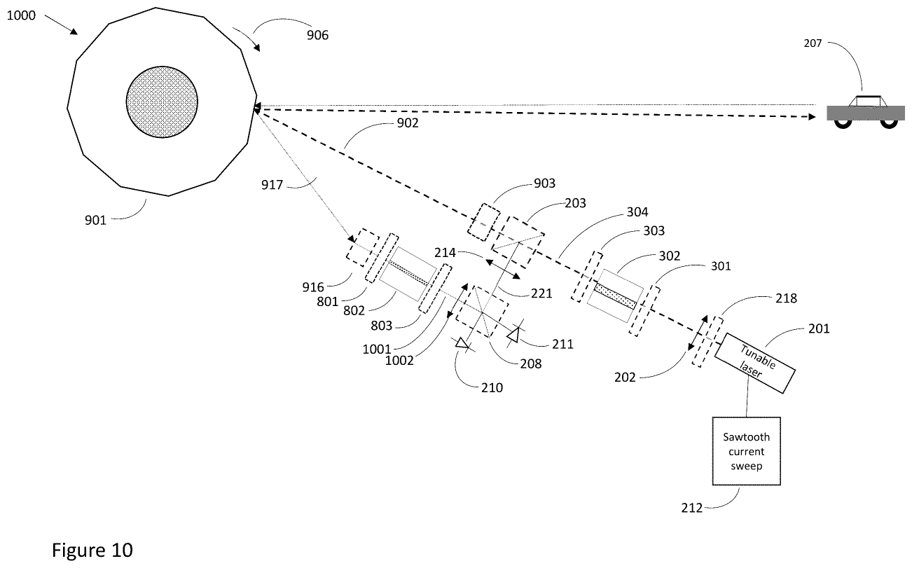

A fifth embodiment of the invention is shown in FIG. 10. The system can be implemented with free-space optics as shown in this figure or with fiber optical components. The laser frequency is controlled by an external current modulator (211) that provides the correct waveform to create a linear sweep (101) of the laser's frequency (103). A typical sweep frequency could span 3 GHz with a 1 kHz sawtooth frequency (101). The system can use laser diode epi-material operating in the range of 1300 nm to 1700 nm. The output of the laser is collimated by the micro-optic or an optic (218) and then coupled into the semiconductor optical amplifier (302) which can be one of the designs shown in FIGS. 4 (400) and 5 (500). The output of the semiconductor optical amplifier is split (203) with 10 mW of laser power sampled to use as the local oscillator. The beam splitter can be a 90:10 for lower power lasers, 99:1 for higher power lasers or 99.9:0.1 for even high-power lasers. The beam splitter can also be between the tunable laser (201) and the semiconductor optical amplifier (302). The local oscillator beam (221) passes through a 50:50 beam splitter (208) to be mixed with the return beam (917). The high-power beam passes through the transmitter optics to create a beam 5 mm in diameter, 4 mm in diameter or smaller, or 6 mm in diameter or larger. This beam reflects off the polygon scanning mirror (901) which has a different angle for each facet in the vertical direction, the motion (906) of the polygon mirror provides the horizontal scan and each facet provides a different horizontal scan in the vertical direction. The beam is assumed to scatter off the Lambertian target and a portion of the beam reflects off the polygon mirror (901) which has moved slightly in the 12 nseconds required to complete a round trip at a 200 meter range. The received beam (917) is collected by a 25 mm diameter receiver optic (916). The received beam is coupled into the semiconductor optical amplifier (802) with a stripe width of 4 μm and can provide up to 30 dB (604) of small signal gain as shown in FIG. 6. The amplified received beam (1001,1002) is mixed with the local oscillator (221) in the 50:50 beam splitter. The mixing of the two beams results in an intensity modulation that is 90 degrees out of phase between the two detectors (1015,1014) creating a double balanced receiver. Each of the photodiode's currents are amplified by a transimpedance amplifier before being analyzed by the receiver electronics to determine range and velocity of the object.

TABLE 6
FMCW Performance with High Power Semiconductor Optical Amplifier and Receiver Pre-Amplifier

| | | CLEAR | | | HAZE | | | Moderate Fog 0.2 km visibility | | |
|---|---|---|---|---|---|---|---|---|---|---|
| | | 10 cm target | | | 10 cm target | | | 10 cm target | | |
| Reflectivity | Laser Power (W) | 10% | 50% | 80% | 10% | 50% | 80% | 10% | 50% | 80% |
| RANGE (m) | 0.03 | 590 | 880 | 980 | 490 | 670 | 730 | 130 | 160 | 170 |
| RANGE (m) | 0.5 | 1,170 | 1,700 | 1,890 | 840 | 1,110 | 1,190 | 180 | 220 | 230 |
| RANGE (m) | 1 | 1,370 | 1,990 | 2,220 | 950 | 1,240 | 1,330 | 200 | 230 | 240 |
| RANGE (m) | 10 | 2,330 | 3,330 | 3,680 | 1,380 | 1,740 | 1,860 | 250 | 280 | 290 |

FMCW performance shows a significant improvement at various power levels above commercially available tunable lasers with 40 mW of laser power. The receiver pre-amplifier has a significant impact on the range as is evident when comparing Table 5 to Table 6. One skilled in the art will recognize that the integrated master oscillator/local oscillator-power amplifier chip (701) described in FIG. 7 can replace the discrete components described in this embodiment.

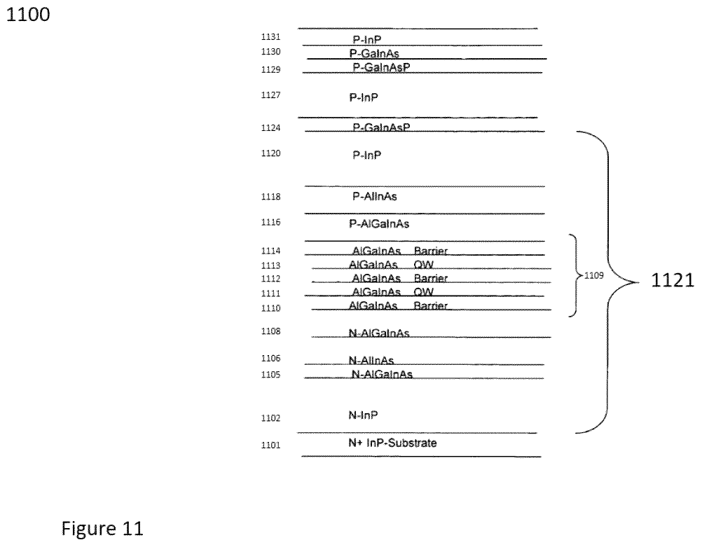

FIG. 11 shows the epi-structure for the device. The invention is a semiconductor laser diode using aluminum gallium indium arsenide, gallium indium arsenide phosphide, indium phosphide. (AlGaInAs/GaInAsP/InP) material system and related combinations. Both the design of the active layer and the design of the optical cavity are optimized to minimize the temperature rise of the active region and to minimize the effects of elevated active layer temperature on the laser efficiency. The result is a high output power semiconductor laser for the wavelengths between 1.30 and 1.70 micrometers. The output power exceeds that exhibited by telecommunication lasers, which are required to have high modulation speeds at the expense of output power.

In a sixth embodiment, the active layer of the device is a strain compensated multi-quantum well structure comprising an intraplanar compressively strained AlGaInAs well and a tensile strained AlGaInAs barrier layer. The thickness of the quantum well is 7 nanometers (nm) or less. The strain is chosen to maximize the conduction band discontinuity while still staying below the critical thickness limit to preclude dislocation formation, so that at high operating temperatures electrons are not lost to the confinement layer due to thermal emission. The width of the well is adjusted to achieve the desired operating wavelength within the constraints of the critical layer thickness.

The active layer is positioned within the center of an optical confinement layer of either the step index type or the graded index type separate confinement heterostructure (GRINSCH). An InP layer on each side forms the optical cladding layer for the optical confinement structure and the multi-quantum well (MQW) active layer. Lateral optical confinement is provided for by either a buried heterostructure or a ridge waveguide structure.

The device is preferably of the vertical current injection type with the semiconductor layers of the SCH and cladding doped p-type, and the other set of the SCH and cladding doped n-type. Lateral current confinement is achieved by either buried Stripe geometry, or a ridge waveguide of raised ridge or dual trench formation. An alternative combination is implant isolation, or mesa isolation, whereby oxide depositions confine the current to the central region of the lateral optical confinement structure.

Another aspect of the invention is the selection of the number of quantum wells in the active layer so as to minimize the thermal power dissipation density in the active layer, combined with a longer cavity length and cavity width to achieve Sufficient gain so that a high optical output power is obtained. Because the area of the junction is larger, the thermal resistance is reduced, thereby resulting in a lower junction temperature for the laser operation at a given output power.

FIG. 11 shows the layer structure of a semiconductor light emitting device that has been constructed according to the principles of the present invention. Specifically, a listing of the epitaxial structure shown. It was fabricated or prepared using conventional III-V compound semiconductor epitaxial growth techniques such as metal organic chemical vapor deposition OMCVD (also referred to as MOCVD) and molecular beam epitaxy (MBE). The starting substrate (1101) is n-type InP, onto which the sequence of layers is epitaxially grown using known methods.

Beginning from the substrate (1101), a 1 micrometer thick n+InP lower cladding layer (1102) with a silicon (Si) doping concentration of 3×10¹⁸ cm⁻³ is grown followed by a transition region 15 nm thick of lattice matched, graded (Al_{0.68}Ga_{0.32})_{0.47}In_{0.53}As to Al_{0.48}In_{0.52}·As (1105-1106) into the separate confinement heterostructure (SCH) layers (1106-1118). Next is the lower graded-index GRIN layer (1108), which is 45 nm thick beginning with Al_{0.48}In_{0.52}As and ending with (Al_{0.59}Ga_{0.41})_{0.47}In_{0.53}As. The silicon doping concentration gradually decreases from the n-type lower cladding (1102) through the transition layers (1105-1106) to the lower GRIN layer (1108) where the silicon doping concentration reaches 5×10¹⁶ cm⁻³.

The undoped laser active layer (1109) has a set of compressively strained AlGaInAs quantum wells (1111 and 1113), which are confined on each side by AlGaInAs barrier layers (1110,1112,1114) under tensile strain such that the strains compensate each other and the critical thickness for dislocations is neutralized. Here, two quantum wells (1111, 1113) are shown each having a well thickness of 7 nm. The barrier layer thicknesses are 6 nm, 9 nm, and 5 nm for layers (1110, 1112, and 1114), respectively.

Next the upper GRIN separate confinement layer (GRINSCH), which is 45 nm thick beginning with (AL_{0.59}Ga_{0.41})_{0.47}In_{0.53}As and ending with an interface layer of Al_{0.48}In_{0.52}As, which is grown on top of the laser active layer (1119). Included in layer (1118) is an additional layer of 5 nm of Al_{0.48}In_{0.52}As. The p-type Zn doping concentration gradually increased from 5×10¹⁶ cm⁻³ as growth proceeds toward the completion of layer (1118), where the concentration reaches 1×10¹⁷ cm⁻³. Alternatively, a step index separate confinement heterostructure (SISCH) could be used in place of the GRINSCH as confinement about the active layer (1109).

Above the GRIN layer (1116-1118) is grown the upper cladding layer (1120) of 1.5 micrometer thick p-type InP Zn-doped at a concentration of 1×10¹⁷ cm 3. The layers (1116, 1118, and 1120) mirror the lower layers of (1106,1105, and 1102) in optical index profile and form the laser waveguide structure (1121) about the active layer (1109).

Low doping of p cladding good for optical transmission. This makes for lower crystal dislocations and optical scattering.

Above the upper cladding layer (1120) are the p-ohmic contact layers (1127-1131). Between the cladding layer (1120) and the contact layers (1127-1131), a 20 nm thick etch stop layer of p-Ga_{0.15}In_{0.85}As_{0.33}P_{0.67}, (1124) is grown in order to provide a controlled stopping depth for etching the ridge waveguide during the laser processing. Next a 1 micrometer thick p-InP layer (1127) Zn-doped at a concentration of 4×10¹⁷ cm⁻³ is grown followed by a p-type Ga_{0.29}In_{0.71}AS_{0.62}P_{0.38} (1129) Zn-doped at 2×10¹⁸ cm⁻³ graded to 1×10¹⁸ cm⁻³ Zn-doped Ga_{0.47}In_{0.53}As 30, which will be the ohmic contact formation layer during laser processing. Finally, a capping layer of p-InP (1131) Zn doped at 1×10¹⁸ cm⁻³ is grown to complete the laser layer structure.

The detailed doping levels described are the preferred embodiment, but a range from 25% less to 50% more would be acceptable. The heavier doping densities above 1×10¹⁸ cm⁻³ can range higher by a factor of two to three as an acceptable range, as low electrical resistance is desired from these layers.

The layer thicknesses set forth above are the preferred embodiment, but a variation of 10% more or less is acceptable.

Consider now the quantum well dimensions and number for the preferred high-power application. Prior work has focused on lasers that required sufficient modulation bandwidth for telecommunications data transmission, which favored single mode short resonator cavity lengths such that the electrical impedance of the device is well matched for high-speed operation. For high optical output power, longer cavities are preferred as will be discussed below regarding heat dissipation. Secondly, good electron confinement to the quantum well with barriers that are significantly higher than the thermal Voltage or the expected non-thermal energy distribution of the electron energies within the junction active area is necessary.

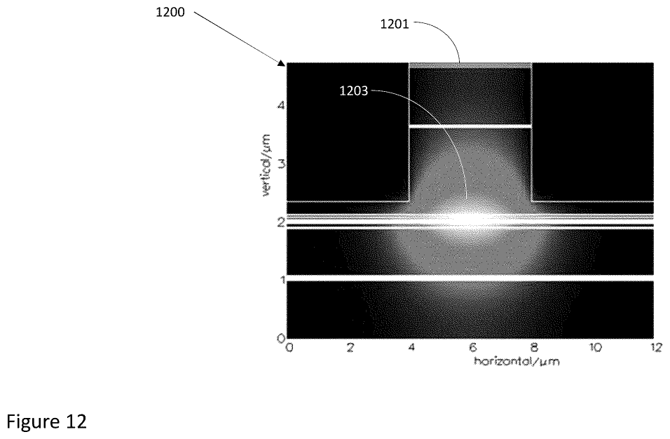

FIG. 12 shows a transverse slice through the semiconductor optical amplifier which is the basis for the LiDAR system described in this invention. The mode (1202) is 2.7 μm along the fast axis and 5.2 μm along the slow axis. The slow axis is confined by the etched rib (1201) which is 4 μm wide and is a real index guide. This is a cross section for the two-amplifier designs shown in FIG. 6. The fast axis confinement is descried in detail in FIG. 11.

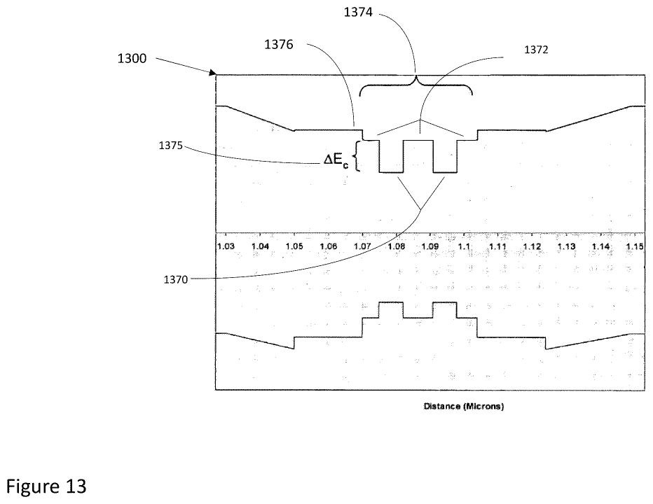

FIG. 13 shows the active layer band diagram schematically. Here, two quantum wells (1370) are shown. In the strain compensated case of compressively strained AlGaInAs wells, the barrier layers (1372) are under tensile strain, with the strain and thickness planned to Sum to Zero stress outside of the active layer well structure (1374). The outside AlGanAs layers (1376) are latticed-matched to the InP lattice constant. Table 7 shows examples of the parameters and desired emission wavelength of the present invention.

TABLE 7

| Run | Structure | Material | Bandgap(nm) | Strain(%) | Width(nm) | ΔE_{c}(eV) |
|---|---|---|---|---|---|---|
| A | Barrier | (Al_{0.3}Ga_{0.7})_{0.58}In_{0.42}As | 1094 | −0.8 | 9 | |
| | Quantum | (Al_{0.32}Ga_{0.68})_{0.29}In_{0.71}As | 1505 | 1.2 | 7 | 0.2 |
| | Well | | | | | |
| B | Barrier | (Al_{0.3}Ga_{0.7})_{0.58}In_{0.42}As | 1094 | −0.8 | 9 | |
| | Quanturn | (Al_{0.46}Ga_{0.54})_{0.29}In_{0.71}As | 1415 | 1.2 | 7 | 0.15 |
| | Well | | | | | |
| C | Barrier | (Al_{0.45}Ga_{0.55})_{0.58}In_{0.42}As | 980 | −0.8 | 9 | |
| | Quantum | (Al_{0.54}Ga_{0.46})_{0.29}In_{0.71}As | 1354 | 1.2 | 7 | 0.15 |
| | Well | | | | | |

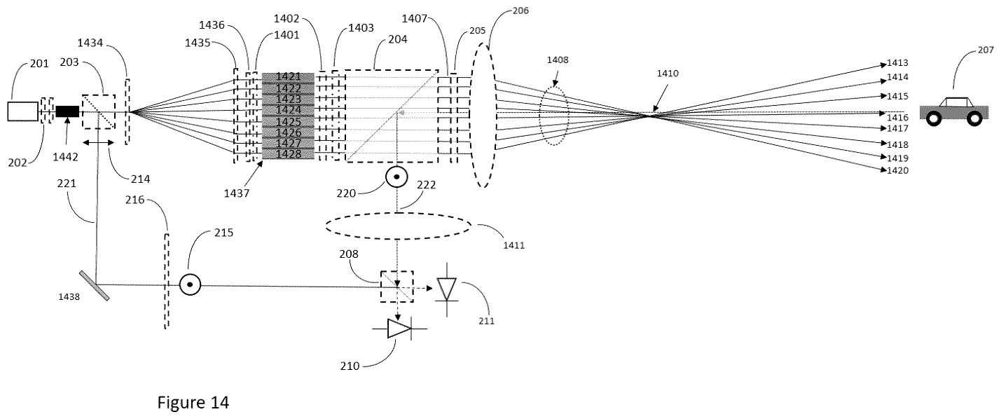

A seventh embodiment of the invention is shown in FIG. 14, which is a means to add electronic scanning to a laser rangefinder and make it a low-resolution LIDAR system. A tunable laser (201) is collimated by a micro-lens (202). Most tunable lasers are sensitive to optical feedback, so an optical isolator (1442) with 30 dB or more isolation is used in the system to prevent feedback from disrupting the lasing wavelength. The beam is split into two beams by a beam sampler that can be a 90:10 splitter, a 98:2 splitter or a 99.9:0.1 splitter depending on the amount of power the tunable laser is capable of, and the amount of power required for a local oscillator. A typical tunable laser is about 50 mW, and a typical local oscillator power is 5 mW to 10 mW. All the components in this diagram can be fiber optic based or part of a silicon photonic integrated circuit (PIC). The beam is split n number of times by the beam splitter, (1434), where n>1. The beam splitter can be a fiber optic splitter, a waveguide splitter or a diffractive optic splitter for a free space implementation. For a free space implementation, it is necessary to redirect the beams (1435) to be parallel to the semiconductor optical amplifiers. A free space implementation can be a diffractive optic, a multi-faceted prism, or a cylindrical lens. A fiber optic approach would simply couple the output of the fiber directly to the face of the semiconductor optical amplifier waveguides (1421-1428). Same with a waveguide approach. If free space, then a slow lens array (1436) in combination with a fast axis collimator (1401) are used to launch the free space beam into the array of semiconductor optical amplifiers. Each amplifier's output is simultaneously collimated by a fast axis collimating lens (1402) and the slow axis is collimated by a slow axis lens (1403). To achieve greater range or better circularity a beam transformation optic can be used to rotate the individual beams 90 degrees allowing for a larger optic to be used to circularize the beam. The beams which are all p-polarized pass through the polarization beam splitting cube (203) and are transformed by the ¼ waveplate to right circular polarized light (205) which is then transmitted to the field of view by the transform lens (206).

The beams are individually addressable by turning on and off each of the semiconductor optical amplifiers. These amplifiers nominally transmit 500 mW of optical power as shown in FIG. 6 where only 3 mW or greater optical power is required to saturate the amplifier. With a 50 mW tunable laser, and 10 mW of optical power dedicated to the local oscillator, an unamplified tunable laser can provide sufficient power to address 13-14 amplifiers. To address more amplifiers, a semiconductor optical amplifier can be added after the isolator (1442) and before the beam sampler. This can increase the tunable laser power to 500 mW and allow more than 100 individually addressable semiconductor optical amplifiers to be addressed. As each amplifier is turned on the beam from that amplifier addresses a particular angle in the field of view as shown in the figure. For example, when amplifier (1421) is turned on the LiDAR system is looking for objects along the angle defined by ray (1420). When amplifier (1422) is addressed, the LiDAR system is looking for objects along the angle defined by ray (1419). Amplifier (1423) corresponds to the angle defined by ray (1418). Amplifier (1424) corresponds to the angle defined by ray (1417). Amplifier (1425) corresponds to the angle defined by ray (1416). The object (1409) reflects a portion of the beam back to the receiver (1410) which is now Left Circular Polarized (LCP). The object is assumed to be a Lambertian scatterer so only a small portion of the light incident returns to the receiver lens. The LCP light is converted to s-polarized light relative to the polarization beam splitter (204) by the ¼ waveplate (205). An optical system (1411) collects the light and delivers it to the 50:50 beam splitting cube (208). The local oscillator p-polarized light (214, 221) with respect to the 50:50 beam splitter (208) of the local oscillator reflects off the mirror (1438), passes through a ½ waveplate (216) which rotates the polarization to be s-polarized light with respect to the 50:50 beam splitter cube (208). The local oscillator and the return beams mix in the 50:50 beam splitter cube (208) producing a modulated light intensity proportional to the frequency difference between the current local oscillator wavelength and the wavelength of the return beam. The double balanced receiver photo-diodes (210 and 211) detect the two intensity modulated signals which are then used to determine the range and velocity of the target.

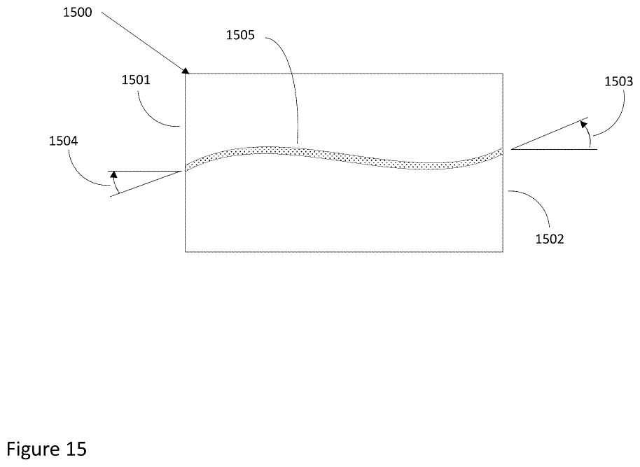

An eighth embodiment of the invention is shown in FIG. 15. Here a semiconductor optical amplifier (1500) with either a single junction or multiple junctions is shown. The input facet (1501) has a low anti-reflection coating and the output facet (1502) has a low anti-reflection coating. A uniform width rib that can be 3 μm, 4 μm or 5 μm is etched into the p-cap layers of the semiconductor optical amplifier epi material to form a lateral confinement of the single mode. The input rib can be at normal to the facet or at some predetermined angle (1504) that is 4 degrees from normal or less or more. This angle helps to prevent unwanted parasitic modes from oscillating in the absence of an injected signal when the angle is 4 degrees or greater. The number of curves (1505) in the rib structure, which helps to suppress unwanted modes, can be 0, 1 or 2. Higher numbers are possible with long waveguide structures. The output of the rib structure can be set at normal to the facet or at some predetermined angle (1503) that is 4 degrees from normal or more or less. When both facets are angled, the round trip loss in the cavity greatly exceeds the gain, and there are no parasitic modes that can oscillate which results in a very high small signal gain that can be 10 dB, 20 dB, 30 dB or 40 dB. The amount of gain is dependent on the drive current, operating temperature, the waveguide shape and the waveguide length.

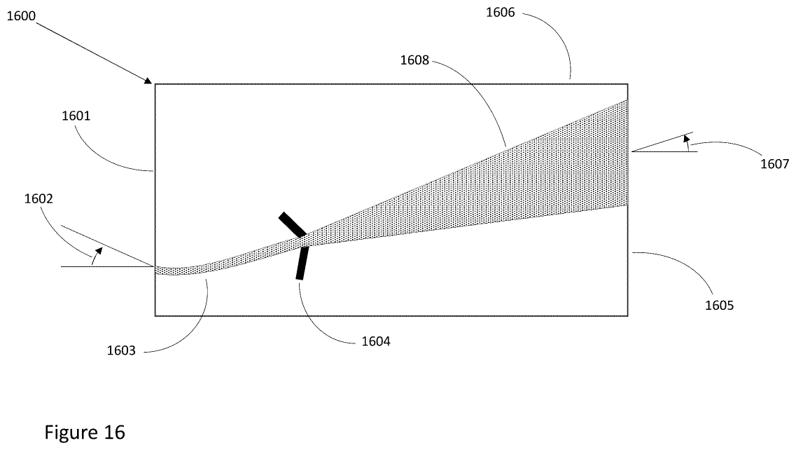

A ninth embodiment of the invention is shown in FIG. 16. Here a semiconductor optical amplifier (1606) with either a single junction or multiple junctions is shown. This semiconductor optical amplifier can be designed to operate at any wavelength region from 1300 nm to 1700 nm depending on the epi-layer design. The input facet (1602) and the output facet (1605) are both coated with a low reflectivity coating. A uniform rib width that can be 3 μm, 4 μm or 5 μm is etched into the p-cap layers of the semiconductor optical amplifier epi material (1603) to form a lateral confinement of the single mode. The input rib can be normal to the facet or at some predetermined angle (1602) that is 4 degrees from normal to the facet or less or more. This angle helps to prevent unwanted parasitic modes from oscillating in the absence of an injected single when the angle is 4 degrees or greater. The number of curves (1605) in the rib structure, which helps to suppress unwanted modes, can be 0, 1 or 2. Higher numbers are possible with long waveguide structures. The rib terminates at the two deep trench etches (1605) which diffracts the beam into the tapered gain section (1608). The tapered gain section expands gently to 20 μm, 30 μm, 60 μm or greater depending on the output power desired. The output of the tapered section can be normal to the output facet (1505) or set at some predetermined angle (1607) from normal which is 4 degrees or greater. The angled incidence on the facets decreases the probability of a parasitic mode oscillating.

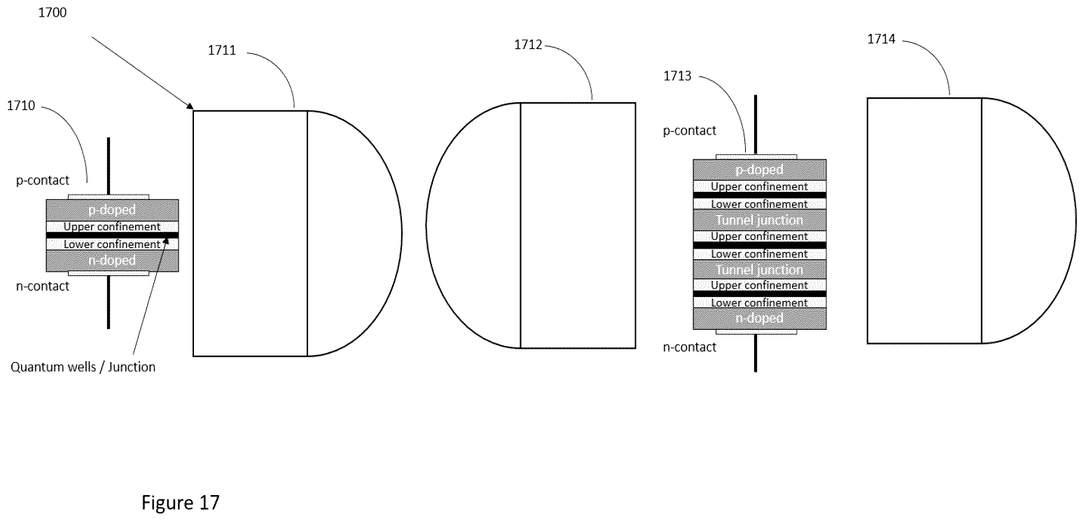

A tenth embodiment of the invention is shown in FIG. 17. A single junction semiconductor device (1710) described in the previous embodiments is collimated by a micro-optic element in the fast axis (1711). For those skilled in the art there is also a slow axis collimator which may or may not be integrated with the fast-axis collimator (1711). The collimated output is then refocused by another micro-optical element (1712) where the vertical axis is now expanded a factor of 2×, 3×, or 4× or more to create a mode on the triple junction device (1713) that overlaps all three semiconductor amplifier layers or junctions. The output of the triple junction is then collimated either with a single fast axis lens (1714) or a more complex micro-optic that corrects the pointing errors associated with each of the off-axis junctions and creates a highly collimated output beam. To those skilled in the art, the master oscillator source may also have a triple junction and may also be integrated onto the same chip along with the power amplifier and the local oscillator splitter described in FIG. 7.

While this invention has been particularly shown and described with references to preferred embodiments thereof, it will be understood by those skilled in the art that various changes in form and details may be made therein without departing from the scope of the invention encompassed by the appended claims.

What is claimed is:

1. A coherent Light Detection and Range (LiDAR) system that uses a seed laser and a high-power semiconductor optical amplifier in the transmitter to improve the range capabilities of the system.

2. The LiDAR system of claim 1 that uses a tunable laser as the seed laser.

3. The LiDAR system of claim 1 that uses a single step index semiconductor optical amplifier with a real index step created by a 3 μm, 4 μm or 5 μm rib to amplify the seed laser to 100 mW, 200 mW, 500 mW or greater and low AR coatings on the input and output facet. The AR coatings are 1% or lower reflectivity to reduce feedback reflections.

4. The LiDAR system of claim 1 that uses a single step index semiconductor optical amplifier with a real index step created by a 3 μm, 4 μm or 5 μm rib at a 4 degree or greater angle from normal to the output facet and input facet to amplify the master oscillator to 100 mW, 200 mW, 500 mW or greater where the rib can be straight or curved or have multiple curves where i is the number of curves and i>1 as long as the exit of the rib is at an angle to the output facet and low AR coatings on the input and output facet. The AR coatings are 1% or lower reflectivity to reduce feedback reflections.

5. The LiDAR system of claim 1 that uses a single step index semiconductor optical amplifier with a real index step created by a 3 μm, 4 μm or 5 μm rib at a 4 degree or greater angle from normal to the input and output facets to amplify the master oscillator to 100 mW, 200 mW, 500 mW or greater where the rib between the facets can have multiple curves where i is the number of curves and i>1 as long as the input and exit of the rib are at an angle to the input and output facets and low AR coatings on the input and output facet. The AR coatings are 1% or lower reflectivity to reduce feedback reflections.

6. The LiDAR system of claim 1 that uses a gain guided strip semiconductor optical amplifier with a gain guided index lateral confinement created by a 10 μm stripe, a 20 μm stripe, a 30 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower reflectivity to reduce feedback reflections.

7. The LiDAR system of claim 1 that uses a gain guided strip semiconductor optical amplifier with a gain guided index lateral confinement at an angle of 4 degrees or greater from normal with respect to the output and input facet created by a 10 μm stripe, a 20 μm stripe, or a 30 μm stripe or larger to provide 0.5 Watt single mode, 1 Watt single mode, 2 Watt single mode or more when injection locked by a single transverse mode master oscillator and low AR coatings on the input and output facet. The AR coatings are 1% or lower reflectivity to reduce feedback reflections.

8. The LiDAR system of claim 1 that uses a tapered gain guided semiconductor optical amplifier with a single mode injection port to amplify the master oscillator to 1 Watts, 2 Watts, or 3 Watts or greater with a stripe that tapers from 3 μm, 4 μm or 5 μm to 50 μm, 60 μm or larger and the single mode rib section can be straight or curved prior to the taper and low AR coatings on the input and output facet. The AR coatings are 1% or lower reflectivity to reduce feedback reflections.

9. The LiDAR system of claim 1 that uses a tapered gain guided semiconductor optical amplifier with a single mode injection port to amplify the master oscillator to 1 Watts, 2 Watts, or 3 Watts or greater with a gain guided stripe that tapers from 3 μm, 4 μm or 5 μm to 20 μm, 30 μm or larger and is tilted at an angle of 4 degrees or greater from normal with respect to the output facet and the single mode rib section can be straight or curved prior to the taper and low AR coatings on the input and output facet. The AR coatings are 1% or lower reflectivity to reduce feedback reflections.

10. The LIDAR system of claim 1 where the master oscillator and a power splitting waveguide are used to create a separate output port on the chip to provide a local oscillator signal to a coherent detection system. The power splitting waveguide may be at any angle of 1°, 2°, 3° or more depending on the power needed for the local oscillator. The port may exit the front facet, the back facet or the sides of the device. All exits will be AR coated with a low AR coating of 1% reflectivity or less.

11. The LIDAR system of claim 1 where the master oscillator is integrated on the same chip as the power splitter and a semiconductor optical amplifier with separate electrical connections to independently power the master oscillator and the power amplifier.

12. The LiDAR system of claim 1 that uses a frequency modulated laser to measure the range of the object when the frequency modulation is ramped up and down in a sawtooth pattern.

13. The LiDAR system of claim 1 that uses a frequency modulated laser to measure the velocity of the object when the frequency modulation is ramped up and down in a sawtooth pattern.

14. The LiDAR system of claim 1 that uses a frequency modulated laser to measure the range of the object when the frequency modulation is ramped up and down in a sinusoidal pattern.

15. The LiDAR system of claim 1 that uses a frequency modulated laser to measure the velocity of the object when the frequency modulation is ramped up and down in a sinusoidal pattern.

16. The LIDAR system of claim 1 that uses a doppler shift of the return beam to measure the velocity of the object.

17. The LiDAR system of claim 1 that uses the micro-doppler spectrum to characterize the vibration spectrum of the object.

18. The LiDAR system of claim 1 that uses a pseudo-random code to measure the range of the object.

19. The LiDAR system of claim 1 that uses a pseudo-random code to determine the distance and velocity of the object.

20. The LiDAR system of claim 1 that uses phase modulation to determine the distance and velocity of the object.

21. The LiDAR system of claim 1 that operates at a wavelength in the band of 1225 nm-1700 nm.

22. The LiDAR system of claim 1 that uses a multi-junction epi-structure for the semiconductor optical amplifier where n is the number of junctions and n>1.

23. The LiDAR system of claim 1 that is integrated into a GaAs photonic integrated chip.

24. The LiDAR system of claim 1 that is integrated into a Silicon photonic integrated chip.

25. The LiDAR system of claim 1 that is integrated into an InP photonic integrated chip.

26. The LiDAR system of claim 1 that uses a lens pair to couple the output of the single junction master oscillator to the multi-junction epi-structure where n is the number of junctions and n>1.
